(19) United States
(12) Patent Application Publication
(10) Pub. No.: US 2026/0107528 A1
(43) Pub. Date: Apr. 16, 2026

(54) NANOSHEET SEMICONDUCTOR DEVICE WITH AIR INNER SPACER AND METHOD FOR MANUFACTURING THE SAME

(71) Applicant: TAIWAN SEMICONDUCTOR MANUFACTURING COMPANY, LTD., Hsinchu (TW)

(72) Inventors: Tze-Chung LIN, Hsinchu (TW); Fang-Wei LEE, Hsinchu (TW); Yu-Wei LU, Hsinchu (TW); Chia-Hao YU, Hsinchu (TW); Wei-Ting YEH, Hsinchu (TW); Yu-Yun PENG, Hsinchu (TW); Keng-Chu LIN, Hsinchu (TW); Pinyen LIN, Hsinchu (TW)

(73) Assignee: TAIWAN SEMICONDUCTOR MANUFACTURING COMPANY, LTD., Hsinchu (TW)

(21) Appl. No.: 18/915,772

(22) Filed: Oct. 15, 2024

(51) Int. Cl. H01L 29/06; H01L 21/8238; H01L 27/092; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 84/0167; H10D 84/038; H10D 84/85

(57) ABSTRACT

A method for manufacturing a semiconductor device includes: forming a stack portion including sacrificial features and channel features which are alternately stacked, so that lateral recesses are formed beside the sacrificial features; respectively forming semipermeable features in the lateral recesses, each of the semipermeable features laterally covering a corresponding one of the sacrificial features; forming sacrificial layer portions on the semipermeable features, each of the sacrificial layer portions being disposed on a corresponding one of the semipermeable features; forming inner spacers on the sacrificial layer portions, each of the inner spacers laterally covering a corresponding one of the sacrificial layer portions; removing the sacrificial features; treating the semipermeable features with an etching process; and removing the sacrificial layer portions through the semipermeable features to form air inner spacers, each of which is defined by a corresponding one of the semipermeable features and a corresponding one of the inner spacers.

### BACKGROUND

With rapid development of integrated circuit (IC) technology, economic benefit of an IC chip increases due to an increased functional density thereof (i.e., an increase in a number of semiconductor devices per chip area). Semiconductor devices, such as nanosheet field-effect transistors (FETs), have attracted much attention due to superior device performance and low power consumption. Nevertheless, in order to meet various application requirements, improvement in the electrical characteristics of the semiconductor devices is required.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor device in accordance with some embodiments.

FIGS. 2A to 17B are schematic views illustrating some intermediate stages of the method as depicted in FIGS. 1A and 1B in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “uppermost,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

With continuous advancement of semiconductor technology, various transistor structures (e.g., a nanosheet field-effect transistor structure, a forksheet field-effect transistor structure, a gate-all-around field-effect transistor (GAAFET) structure, etc.) can be manufactured and accommodated in an integrated circuit (IC) chip, which is conducive to increasing an economic benefit of the IC chip. Nanosheet semiconductor devices (e.g., nanosheet field-effect transistors) have been applied in various electrical products due to superior device performance. In order to meet increased market demand, there is a need to improve the device performance and reduce power consumption of the nanosheet semiconductor devices.

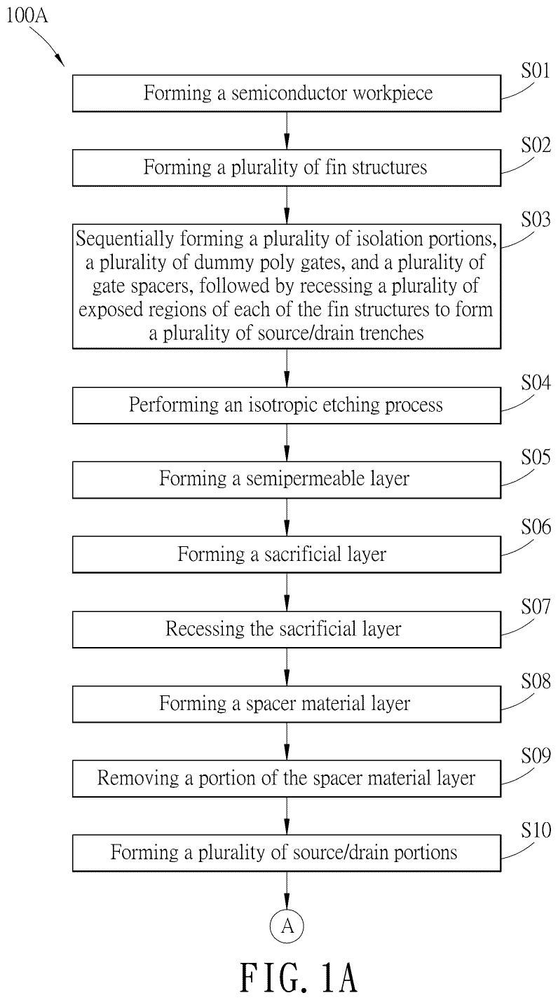

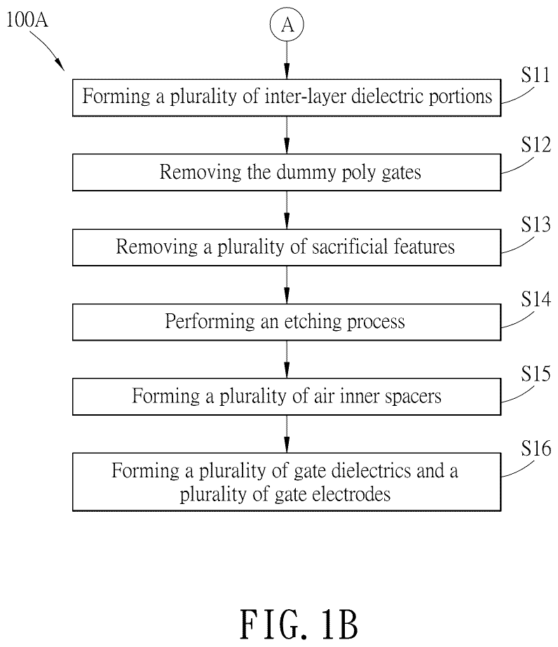

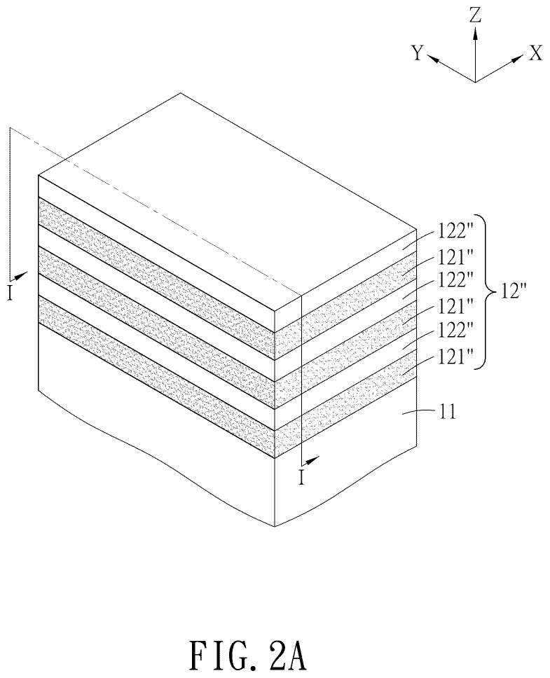

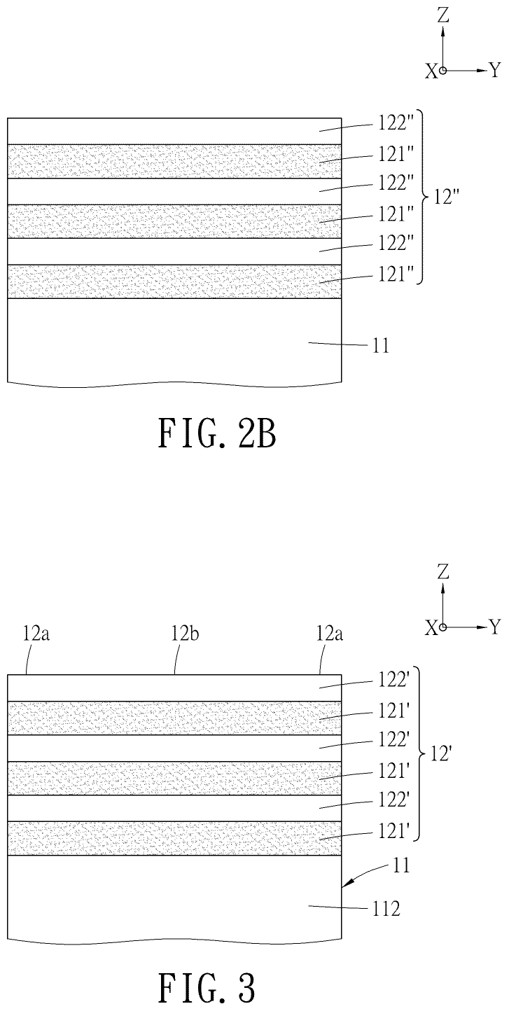

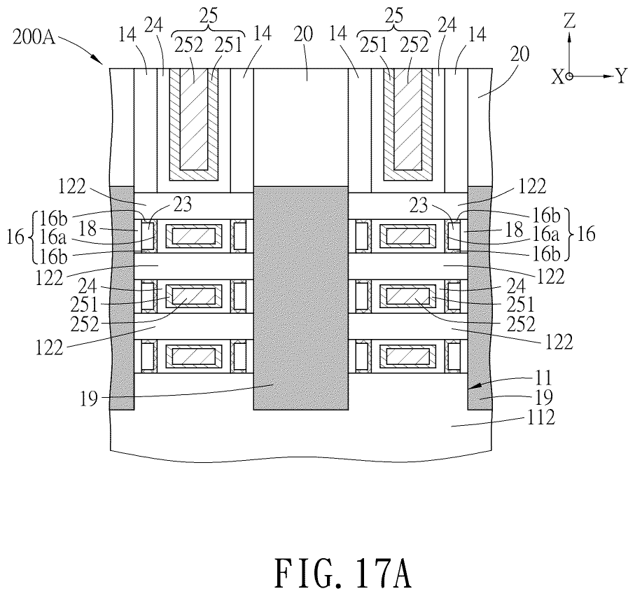

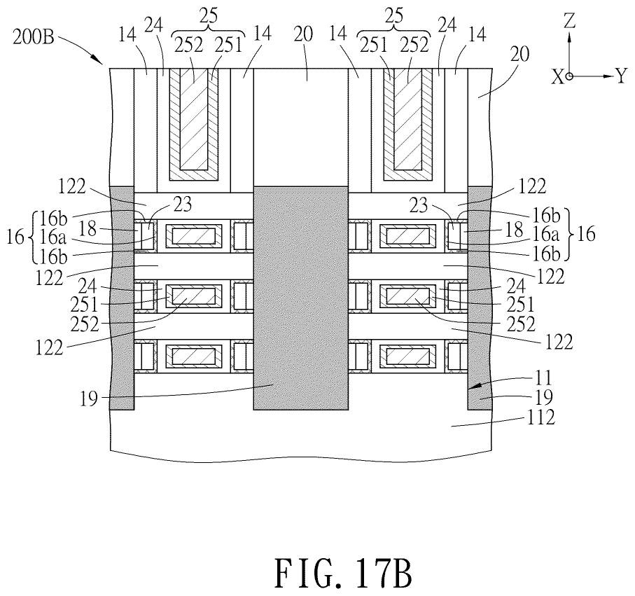

The present disclosure is directed to a semiconductor device and a method for manufacturing the same. FIGS. 1A and 1B are flow diagrams illustrating a method 100A for manufacturing a semiconductor device 200A shown in FIG. 17A or a semiconductor device 200B shown in FIG. 17B in accordance with some embodiments. FIGS. 2A to 16 illustrate schematic views of some intermediate stages of the method 100A. Some portions may be omitted in FIGS. 2A to 16 for the sake of brevity. Additional steps can be provided before, after or during the method 100A, and some of the steps described herein may be replaced by other steps or be eliminated.

Referring to FIG. 1A and the example illustrated in FIGS. 2A and 2B, the method 100A begins at step S01, where a semiconductor workpiece is formed. FIG. 2B illustrates a cross-sectional view taken along line I-I of FIG. 2A. The semiconductor workpiece includes a semiconductor substrate 11 and a nanosheet stack 12″.

The semiconductor substrate 11 may include, for example, but not limited to, an elemental semiconductor or a compound semiconductor. In some embodiments, the elemental semiconductor includes a single species of atoms, such as silicon or germanium in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 11 may include a multilayer compound semiconductor structure. In some embodiments, the semiconductor substrate 11 may be a semiconductor on insulator (SOI) (e.g., silicon germanium on insulator (SGOI)). Generally, an SOI substrate includes a layer of a semiconductor material, such as epitaxial silicon, germanium, silicon germanium, or combinations thereof. The SOI substrate may be doped with a p-type dopant, for example, but not limited to, boron, aluminum, or gallium. Other suitable p-type dopant materials are within the contemplated scope of the present disclosure. Alternatively, the SOI substrate may be doped with an n-type dopant, for example, but not limited to, nitrogen, phosphorous, or arsenic. Other suitable n-type dopant materials are within the contemplated scope of the present disclosure.

The nanosheet stack 12″ is disposed on the semiconductor substrate 11 in a Z direction normal to the semiconductor substrate 11. The nanosheet stack 12″ includes a plurality of sacrificial layers 121″ and a plurality of channel layers 122″ disposed to alternate with the sacrificial layers 121″ in the Z direction. In some embodiments, the nanosheet stack 12″ is a stack of semiconductor materials. In some embodiments, the sacrificial layers 121″ are made of a first semiconductor material, and the channel layers 122″ are made of a second semiconductor material that is different from the first semiconductor material, so that each layer of the channel layers 122″ has an etching selectivity (or an etching rate) different from that of each layer of the sacrificial layers 121″. In some embodiments, the first semiconductor material may be silicon germanium, and the second semiconductor material may be silicon, so that each layer of the sacrificial layers 121″ has an etching selectivity (or an etching rate) greater than that of each layer of the channel layers 122″. In some embodiments, the nanosheet stack 12″ may be formed on the semiconductor substrate 11 by a suitable deposition process (for example, but not limited to, chemical vapor deposition (CVD), atomic layer deposition (ALD), etc.), a suitable epitaxial growth process (for example, but not limited to, molecular beam epitaxy (MBE), selective epitaxial growth (SEG) process, etc.), or other suitable processes.

Referring to FIG. 1A and the example illustrated in FIG. 3, the method 100A then proceeds to step S02, where the semiconductor workpiece is patterned to form a plurality of fin structures 12′ that extend in a Y direction transverse to the Z direction and parallel to the semiconductor substrate 11, and that are spaced apart from one another by trenches (not shown) in an X direction transverse to the Z direction and the Y direction. One of the fin structures 12′ is shown in FIG. 3. Step S02 may be performed by a photolithography process, which includes an etching process. The etching process may be, for example, but not limited to, an anisotropic etching process. After this step, the semiconductor substrate 11 is formed into a lower portion (not shown) and a plurality of fin portions 112 that are disposed on the lower portion and that are spaced apart from one another in the X direction. Each of the fin structures 12′ is disposed on a corresponding one of the fin portions 112 of the semiconductor substrate 11, and includes a plurality of sacrificial layer portions 121′ and a plurality of channel layer portions 122′ disposed to alternate with the sacrificial layer portions 121′ in the Z direction. In some embodiments, an upper surface of each of the fin structures 12′ may have a plurality of covered regions 12a and a plurality of exposed regions 12b that are separated from one another in the Y direction. Two of the covered regions 12a and one of the exposed regions 12b are shown in FIG. 3.

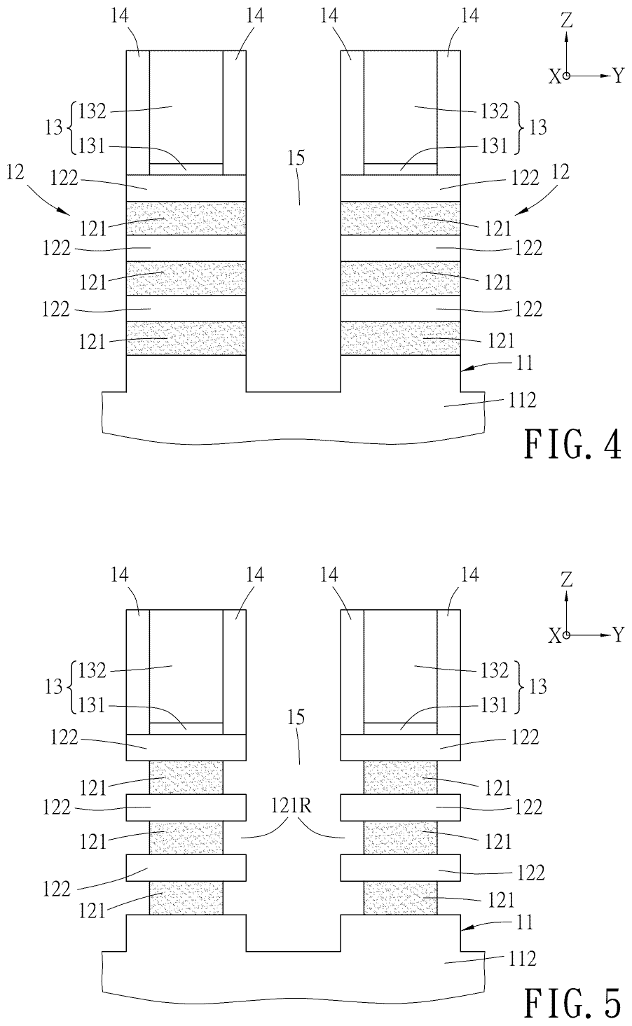

Referring to FIG. 1A and the example illustrated in FIG. 4, the method 100A then proceeds to step S03, where a plurality of isolation portions (not shown), a plurality of dummy poly gates 13 and a plurality of gate spacers 14 are sequentially formed on the structure shown in FIG. 3, followed by recessing the exposed regions 12b of each of the fin structures 12′. Step S03 may include sub-steps (i) to (iv).

In sub-step (i) of step S03, the isolation portions are formed on the lower portion of the semiconductor substrate 11. Each pair of the isolation portions is located at two opposite sides of a corresponding one of the fin portions 112 of the semiconductor substrate 11 so as to separate and isolate the fin structures 12′ (see FIG. 3) from each other. The two opposite sides of the corresponding one of the fin portions 112 are opposite to each other in the X direction. In some embodiments, the isolation portions may be made of an oxide-based material (e.g., silicon oxide), a nitride-based material (e.g., silicon nitride), or a combination thereof. Other suitable materials for the isolation portions are within the contemplated scope of the present disclosure. In some embodiments, the isolation portions may be formed by a suitable deposition process, for example, but not limited to, CVD or physical vapor deposition (PVD). Other suitable processes for forming the isolation portions are within the contemplated scope of the present disclosure. In some embodiments, each of the isolation portions may be a portion of a shallow trench isolation (STI), a deep trench isolation (DTI), or other suitable isolation structures.

In sub-step (ii) of step S03, the dummy poly gates 13 are formed on the isolation portions and over the fin structures 12′, and are spaced apart from each other in the Y direction. In some embodiments, each of the dummy poly gates 13 may include a dummy gate dielectric 131 and a dummy gate electrode 132.

The dummy gate dielectric 131 of each of the dummy poly gates 13 is disposed on a corresponding one of the covered regions 12a of each of the fin structures 12′ (see FIG. 3). The dummy gate dielectric 131 may be made of an oxide-based material (e.g., silicon oxide). Other suitable materials for the dummy gate dielectric 131 are within the contemplated scope of the present disclosure.

The dummy gate electrode 132 is disposed on the dummy gate dielectric 131. The dummy gate electrode 132 may include polysilicon. Other suitable materials for the dummy gate electrode 132 are within the contemplated scope of the present disclosure.

In sub-step (iii) of step S03, each pair of the gate spacers 14 is respectively formed at two opposite sides of a corresponding one of the dummy poly gates 13 in the Y direction. In some embodiments, each of the gate spacers 14 may be formed as a single layer structure or a multi-layered structure. Sub-step (iii) may be performed by depositing a spacer material layer on the dummy poly gates 13 and the exposed regions 12b of the fin structures 12′ by a suitable deposition process, for example, but not limited to, CVD, ALD, or other suitable deposition processes, followed by conducting an anisotropic dry etching process until portions of the spacer material layer, which are respectively formed on the exposed regions 12b of the fin structures 12′ and an upper surface of each of the dummy poly gates 13, are removed such that remaining portions of the spacer material layer serve as the gate spacers 14. The spacer material layer for forming the gate spacers 14 may include, for example, but not limited to, silicon oxide, silicon nitride, silicon oxynitride, silicon carbon nitride, silicon oxycarbonitride, or low-dielectric constant (k) materials. Other suitable materials for forming the spacer material layer are within the contemplated scope of the present disclosure.

In sub-step (iv) of step S03, the exposed regions 12b of the fin structures 12′ are recessed by a suitable etching process, for example, but not limited to, dry etching, wet etching, other suitable etching processes, or combinations thereof, so as to form a plurality of source/drain trenches 15 that are spaced apart from one another in the Y direction. One of the source/drain trenches 15 is shown in FIG. 4. After sub-step (iv) of step S03, the fin structures 12′ are formed into a plurality of stack portions 12. Each of the stack portions 12 includes a plurality of sacrificial features 121 (formed from the sacrificial layer portions 121′ (see FIG. 3)) and a plurality of channel features 122 (formed from the channel layer portions 122′ (see FIG. 3)).

Referring to FIG. 1A and the example illustrated in FIG. 5, the method 100A then proceeds to step S04, where the sacrificial features 121 are laterally recessed, so as to form a plurality of lateral recesses 121R. Step S04 may be performed by an isotropic etching process, for example, but not limited to, a wet etching process or other suitable etching processes. The lateral recesses 121R are disposed beside the recessed sacrificial features 121. Each of the lateral recesses 121R is disposed between two corresponding ones of the channel features 122.

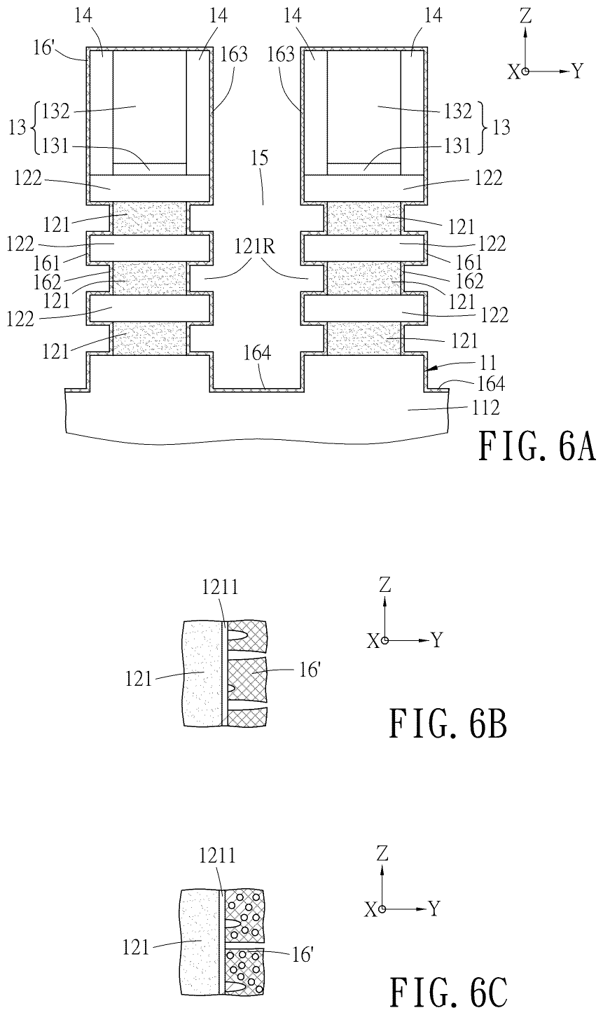

Referring to FIG. 1A and the examples illustrated in FIGS. 6A to 6C, the method 100A then proceeds to step S05, where a semipermeable layer 16′ is conformally formed on the structure shown in FIG. 5. FIGS. 6B and 6C are partially enlarged views of the structure shown in FIG. 6A, respectively.

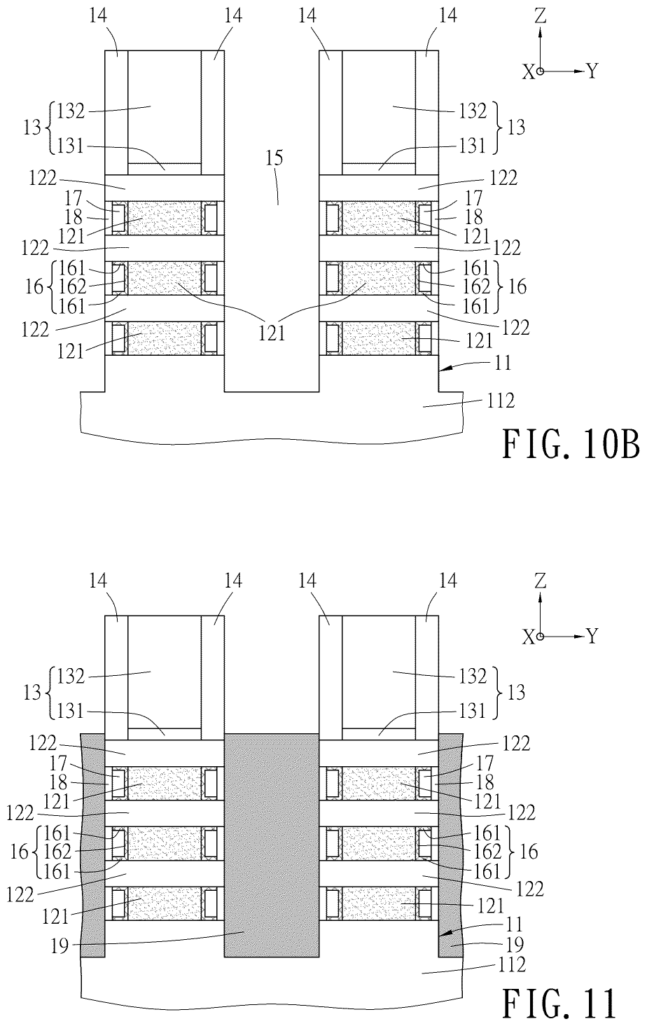

As shown in FIGS. 6A to 6C, in some embodiments, the semipermeable layer 16′ is made of a low-k dielectric material, for example, but not limited to, silicon carbonitride, silicon oxycarbonitride, or a combination thereof. Other suitable low-k materials for forming the semipermeable layer 16′ are within the contemplated scope of the present disclosure. In some embodiments, the semipermeable layer 16′, which is made of the low-k dielectric material, may have a mesoporous structure. In some embodiments, the semipermeable layer 16′ is formed by a suitable deposition process, for example, but not limited to, ALD. Other suitable deposition processes for forming the semipermeable layer 16′ are within the contemplated scope of the present disclosure. In some embodiments, a precursor may be used in the deposition process for forming the semipermeable layer 16′. When the semipermeable layer 16′ is made of silicon carbonitride, the precursor used in the deposition process may include, for example, but not limited to, hexachlorodisilane (HCD), propylene, ammonia, or combinations thereof. When the semipermeable layer 16′ is made of silicon oxycarbonitride, the precursor used in the deposition process may include, for example, but not limited to, Calypso (CH₂Cl₆Si₂), ammonia, or a combination thereof. Other suitable precursors for forming the semipermeable layer 16′ are within the contemplated scope of the present disclosure. In some embodiments, in the deposition process, the semipermeable layer 16′ may be deposited at a temperature ranging from about 300° C. to about 650° C. If the temperature is lower than 300° C., the semipermeable layer 16′ may have a poor uniformity, a poor quality or a poor roughness. If the temperature is greater than 650° C., each of the sacrificial features 121 and the channel features 122 may be undesirably subjected to thermal diffusion, which may result in a change in a thickness of the each of the sacrificial features 121 and the channel features 122, and may further affect a thickness of each of a plurality of gate dielectrics 24 or a thickness of each of a plurality of gate electrodes 25 (which will be described hereinafter with reference to FIG. 17A or FIG. 17B). In some embodiments, the semipermeable layer 16′ may have a thickness ranging from about 15 Å to about 25 Å. If the thickness of the semipermeable layer 16′ is less than 15 Å, the semipermeable layer 16′ may have a poor coverage on the structure shown in FIG. 5. If the thickness of the semipermeable layer 16′ is greater than 25 Å, a size of each of a plurality of inner spacers 18 may be reduced (which will be described hereinafter with reference to FIG. 10A or FIG. 10B).

In some embodiments, the semipermeable layer 16′ includes a plurality of semipermeable layer portions 161, 162, 163, 164. Each of the semipermeable layer portions 161 covers a corresponding one of the channel features 122. Each of the semipermeable layer portions 162 is disposed on a side surface of a corresponding one of recessed sacrificial features 121, and connects corresponding two adjacent ones of the semipermeable layer portions 161. Each of the semipermeable layer portions 163 covers a corresponding pair of the gate spacers 14 and an upper surface of the dummy gate electrode 132 of a corresponding one of the dummy poly gates 13. Each of the semipermeable layer portions 164 covers an upper surface of a corresponding one of the fin portions 112.

As shown in FIG. 6B, in some embodiments, the mesoporous structure of the semipermeable layer 16′ (made of the low-k dielectric material) may include a plurality of pinholes. As shown in FIG. 6C, in some embodiments, the mesoporous structure of the semipermeable layer 16′ may include a plurality of pinholes and a plurality of cages.

In some embodiments, the semipermeable layer 16′ may be a self-aligned oxidation layer, which is formed by a self-aligned oxidation process. In this case, each of the semipermeable layer portions 161 is made of silicon oxide. Each of the semipermeable layer portions 162 is made of silicon germanium oxide. Each of the semipermeable layer portions 163 includes oxide of the gate spacers 14 and oxide of the dummy gate electrodes 132. Each of the semipermeable layer portions 164 is made of silicon oxide. In this case, the self-aligned oxidation process is performed by a wet treatment, a dry treatment, or a combination thereof. In some embodiments, a chemical agent used in the wet treatment may include, for example, but not limited to, dilute ozone (dO₃), hydrogen peroxide, or a combination thereof. Other suitable chemical agents used in the wet treatment are within the contemplated scope of the present disclosure. In some embodiments, the dry treatment is a gas plasma treatment. In some embodiments, the dry treatment may be performed using, for example, but not limited to, ozone gas, oxygen gas, oxygen radical species, steam, or combinations thereof. Other suitable gases or radical species used in the dry treatment are within the contemplated scope of the present disclosure. In some embodiments, each of the semipermeable layer portions 163 may have a thickness less than a thickness of each of the semipermeable layer portions 161, 162, 164. In some embodiments, the semipermeable layer 16′, which is formed as the self-aligned oxidation layer, may include a plurality of pinholes.

In some embodiments, after laterally recessing the sacrificial features 121 (i.e., step S04) and before formation of the semipermeable layer 16′ (i.e., step S05), an oxide layer 1211 may be formed on a side surface of each of the recessed sacrificial features 121 (see FIGS. 6B and 6C).

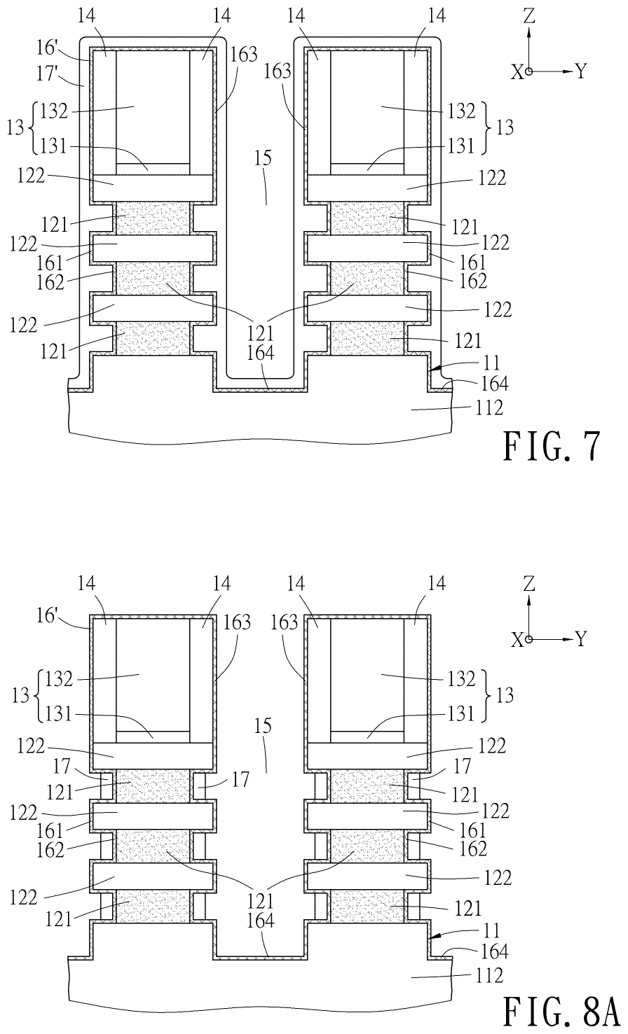

Referring to FIG. 1A and the example illustrated in FIG. 7, the method 100A then proceeds to step S06, where a sacrificial layer 17′ is formed on the structure shown in FIG. 6A. In some embodiments, the sacrificial layer 17′ may be made of, for example, but not limited to, silicon germanium, silicon oxide, a polymeric material, or combinations thereof. Other suitable materials for forming the sacrificial layer 17′ are within the contemplated scope of the present disclosure. In some embodiments, the polymeric material may include, for example, but not limited to, carbon, hydrogen, oxygen, silicon, nitrogen, or combinations thereof. In some embodiments, when the sacrificial layer 17′ is made of silicon germanium or silicon oxide, the sacrificial layer 17′ may be formed by a suitable epitaxial growth process, for example, but not limited to, a furnace growth process. Other suitable processes (e.g., CVD or ALD) are within the contemplated scope of the present disclosure.

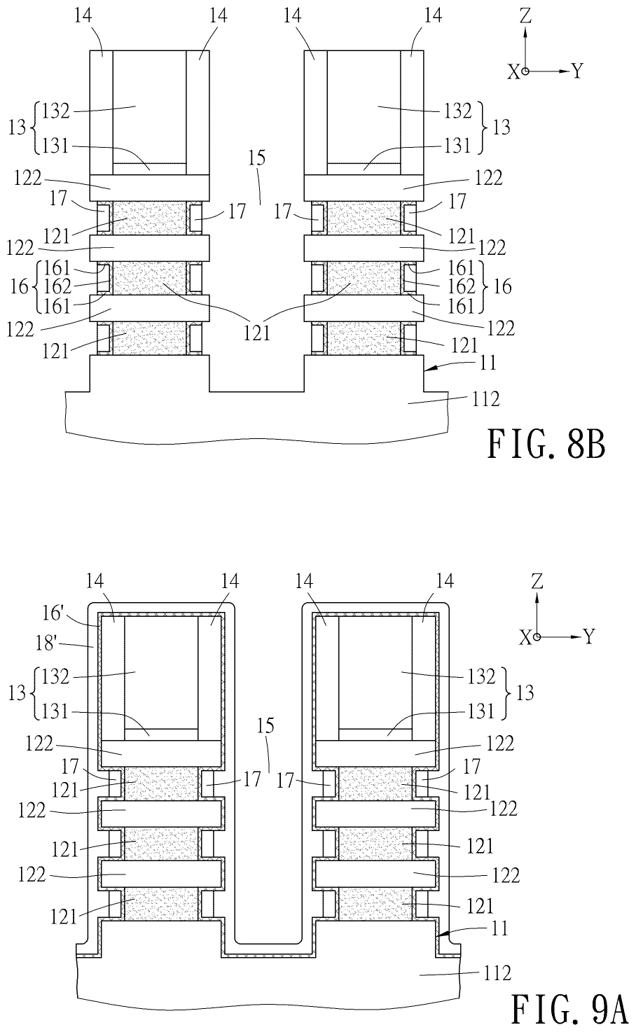

Referring to FIG. 1A and the examples illustrated in FIGS. 8A and 8B, the method 100A then proceeds to step S07, where the sacrificial layer 17′ is recessed, so as to form a plurality of sacrificial layer portions 17. Step S07 may be performed by an isotropic etching process, for example, but not limited to, a wet etching process or other suitable etching processes. As shown in FIG. 8A, when the semipermeable layer 16′ is made of the low-k dielectric material (e.g., silicon carbonitride, silicon oxycarbonitride, or a combination thereof), the semipermeable layer 16′ remains intact after this step. As shown in FIG. 8B, in some embodiments, when the semipermeable layer 16′ is the self-aligned oxidation layer, a wet clean process may be further performed on the structure obtained after the isotropic etching process, so as to remove parts of the semipermeable layer portions 161 and the semipermeable layer portions 163, 164. In this case, remaining parts of the semipermeable layer portions 161 and the semipermeable layer portions 162 may cooperatively form a plurality of semipermeable features 16, where each of the semipermeable features 16 includes a pair of the semipermeable layer portions 161 remaining after the wet clean process and one of the semipermeable layer portions 162 interconnecting the pair of the semipermeable layer portions 161. In some embodiments, each of the sacrificial layer portions 17 is partially covered by a corresponding one of the semipermeable features 16. In some embodiments, each of the sacrificial layer portions 17 and a corresponding one of the semipermeable features 16 are located in a corresponding one of the lateral recesses 121R (see FIG. 5 or 6A). In some embodiments, each of the semipermeable features 16 laterally covers a corresponding one of the recessed sacrificial features 121.

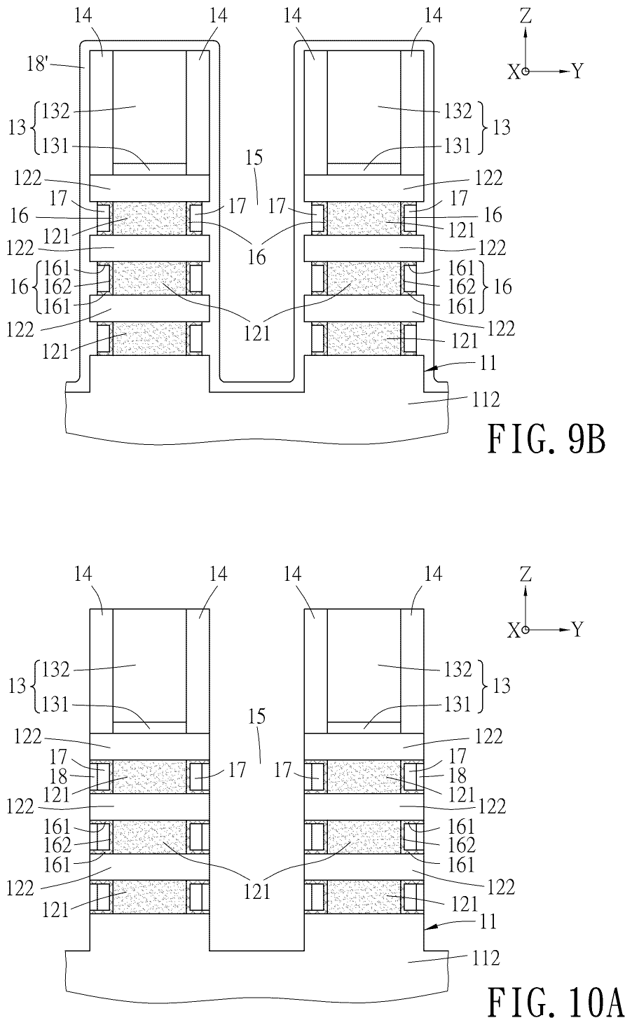

Referring to FIG. 1A and the examples illustrated in FIGS. 9A and 9B, the method 100A then proceeds to step S08, where a spacer material layer 18′ is formed. The structure shown in FIG. 9A is obtained by forming the spacer material layer 18′ on the structure shown in FIG. 8A. The structure shown in FIG. 9B is obtained by forming the spacer material layer 18′ on the structure shown in FIG. 8B. In some embodiments, the spacer material layer 18′ may include, for example, but not limited to, silicon oxide, silicon nitride, silicon oxynitride, silicon carbon nitride, silicon oxycarbonitride, silicon oxycarbide, silicon carbide, aluminum oxide, hafnium oxide, zirconium oxide, or combinations thereof. Other suitable materials for forming the spacer material layer 18′ are within the contemplated scope of the present disclosure. In some embodiments, the spacer material layer 18′ may be formed by a suitable deposition process, for example, but not limited to, CVD or ALD. Other suitable deposition processes for forming the spacer material layer 18′ are within the contemplated scope of the present disclosure.

Referring to FIG. 1A and the examples illustrated in FIGS. 10A and 10B, the method 100A then proceeds to step S09, where a portion of the spacer material layer 18′ is removed. The structure shown in FIG. 10A is obtained by removing the portion of the spacer material layer 18′ of the structure shown in FIG. 9A. The structure shown in FIG. 10B is obtained by removing the portion of the spacer material layer 18′ of the structure shown in FIG. 9B. Step S09 may be performed by a suitable etching process, for example, but not limited to, an isotropic etching process, an anisotropic etching process (e.g., a plasma etching process), or a combination thereof. After this step, remaining portions of the spacer material layer 18′ may be referred to as the inner spacers 18. As shown in FIG. 10A, in this step, the semipermeable layer portions 163, 164 and portions of the semipermeable layer portions 161 of the semipermeable layer 16′ (made of the low-k dielectric material) are also removed so that the semipermeable layer portions 162 and remaining portions of the semipermeable layer portions 161 remain. In this case, each of the remaining portions of the semipermeable layer portions 161 covers a corresponding one of the sacrificial layer portions 17 and a corresponding one of the inner spacers 18. In some embodiments, each of the inner spacers 18 is disposed on a side surface of a corresponding one of the sacrificial layer portions 17, is exposed to a corresponding one of the source/drain trenches 15, and is disposed between corresponding two adjacent ones of the channel features 122. In addition, as shown in FIG. 10B, in some embodiments, each of the inner spacers 18 is disposed on a side surface of a corresponding one of the sacrificial layer portions 17, and is disposed between corresponding two adjacent ones of the channel features 122 but not covered by the portions of the semipermeable layer portions 161 remaining after the etching process.

For purposes of simplicity and clarity, only the structure shown in FIG. 10B is used to illustrate the following steps.

Referring to FIG. 1A and the example illustrated in FIG. 11, the method 100A then proceeds to step S10, where a source/drain portion 19 is formed in each of the source/drain trenches 15 of the structure shown in FIG. 10B (i.e., a plurality of the source/drain portions 19 are formed in this step). In some embodiments, the source/drain portion 19 may have a p-type conductivity, and may include single crystalline silicon, polycrystalline silicon, single crystalline silicon germanium, polycrystalline silicon germanium, or other suitable materials doped with the p-type dopants (as described in step S01) so as to function as a source/drain of a p-type field-effect transistor (p-FET). In some alternative embodiments, the source/drain portion 19 may have an n-type conductivity, and may include single crystalline silicon, polycrystalline silicon, or other suitable materials doped with the n-type dopants (as described in step S01) so as to function as a source/drain of an n-type FET (n-FET). In some embodiments, the source/drain portion 19 is formed in each of the source/drain trenches 15 by a suitable epitaxial growth process, for example, but not limited to, MBE or an epitaxial deposition/partial etch process (e.g., a cyclic deposition-etch (CDE) process and/or a SEG process). Other suitable processes for forming the source/drain portion 19 are within the contemplated scope of the present disclosure.

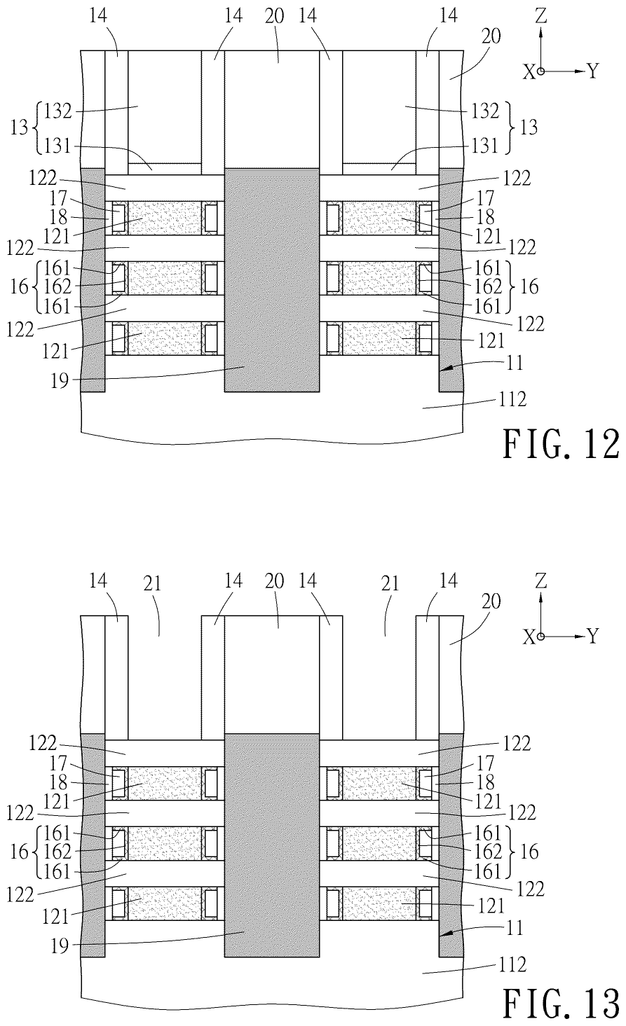

Referring to FIG. 1B and the example illustrated in FIG. 12, the method 100A then proceeds to step S11, where a plurality of inter-layer dielectric (ILD) portions 20 are formed on the source/drain portions 19, respectively. Only one of the ILD portions 20 is shown in FIG. 12. In some embodiments, the ILD portions 20 may include, for example, but not limited to, silicon oxide, silicon nitride, silicon oxynitride, other low-k dielectric materials, or combinations thereof. Other suitable materials for forming the ILD portions 20 are within the contemplated scope of the present disclosure. In some embodiments, the ILD portions 20 may be formed by a suitable deposition process, for example, but not limited to, CVD. Other suitable processes for forming the ILD portions 20 are within the contemplated scope of the present disclosure.

In some embodiments, after formation of the source/drain portions 19 and before formation of the ILD portions 20, a plurality of contact etch stop portions (not shown) may be formed on the source/drain portions 19, respectively. In some embodiments, the contact etch stop portions may include, for example, but not limited to, silicon nitride, carbon-doped silicon nitride, or a combination thereof. Other suitable materials for forming the contact etch stop portions are within the contemplated scope of the present disclosure.

Referring to FIG. 1B and the example illustrated in FIG. 13, the method 100A then proceeds to step S12, where the dummy poly gates 13 (see FIG. 12) are removed, so as to form a plurality of cavities 21. Step S12 may be performed by a suitable etching process, for example, but not limited to, wet etching, dry etching, or a combination thereof. Other suitable etching processes for removing the dummy poly gates 13 are within the contemplated scope of the present disclosure. The cavities 21 are defined by the gate spacers 14 and uppermost ones of the channel features 122.

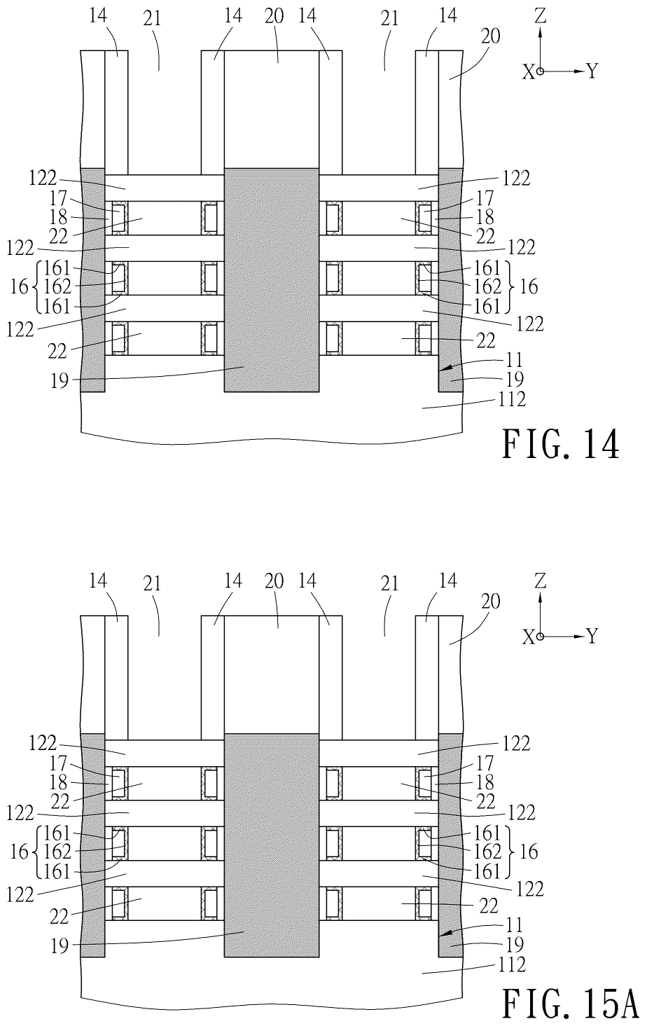

Referring to FIG. 1B and the example illustrated in FIG. 14, the method 100A then proceeds to step S13, where the recessed sacrificial features 121 are removed, so as to form a plurality of cavities 22. Step S13 may be performed by a suitable etching process, for example, but not limited to, an isotropic etching process. Other suitable etching processes for removing the recessed sacrificial features 121 are within the contemplated scope of the present disclosure. The cavities 22 are defined by the semipermeable features 16 and the channel features 122.

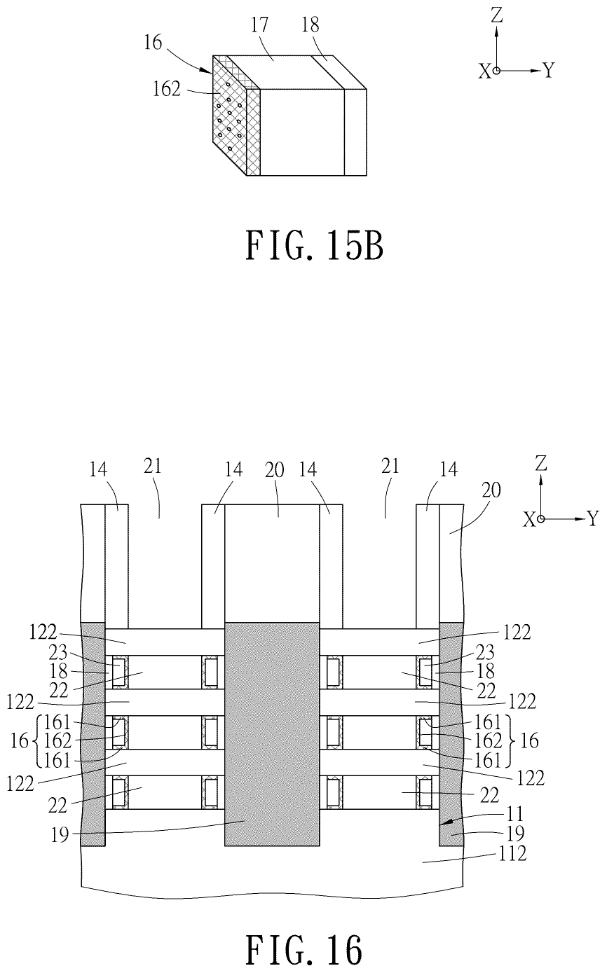

Referring to FIG. 1B and the examples illustrated in FIGS. 15A and 15B, the method 100A then proceeds to step S14, where an etching process is performed to treat the semipermeable features 16 of the structure shown in FIG. 14, so that a number and a size of the pinholes and a number and a size of the cages in each of the semipermeable features 16 increase. FIG. 15B is a partially enlarged view of the structure shown in FIG. 15A. In some embodiments, the etching process may be a dry etching process, a wet etching process, or a combination thereof. When the etching process is a dry etching process (e.g., a plasma etching process), a source gas used in the dry etching process may include, for example, but not limited to, hydrogen chloride gas, chlorine gas, hydrogen fluoride gas, a combination of hydrogen fluoride gas and ammonia gas, or a combination of hydrogen fluoride gas and fluorine gas. Other suitable source gases used in the dry etching process are within the contemplated scope of the present disclosure. When the etching process is a wet etching process, an etchant used in the wet etching process may include, for example, but not limited to, dilute hydrofluoric acid. Other suitable etchants used in the wet etching process are within the contemplated scope of the present disclosure. In some embodiments, when the semipermeable layer portions 162 are formed from the self-aligned oxidation layer, the number and the size of the pinholes and the number and the size of the cages in the semipermeable features 16 may increase after the etching process due to breaking of silicon-oxygen bonds and germanium-oxygen bonds in the semipermeable layer portions 162 during the etching process. In this case, a number of broken germanium-oxygen bonds is greater than a number of broken silicon-oxygen bonds because a bonding energy of the germanium-oxygen bonds is lower than a bonding energy of the silicon-oxygen bonds. In some embodiments, when the semipermeable features 16 are made of the low-k dielectric material (as described in step S05), the number and the size of the pinholes and the number and the size of the cages in the semipermeable features 16 may increase after the etching process due to breaking of silicon-oxygen bonds and silicon-nitrogen bonds in the semipermeable layer portions 162 during the etching process. In some embodiments, the etching process in this step may be referred to as a porosity creation process.

Referring to FIG. 1B and the example illustrated in FIG. 16, the method 100A then proceeds to step S15, where the sacrificial layer portions 17 are removed through the semipermeable features 16 (e.g., through the pinholes and/or the cages), so as to form a plurality of air inner spacers 23.

When the sacrificial layer portions 17 are made of silicon germanium, the sacrificial layer portions 17 may be removed by a suitable etching process, for example, but not limited to, a dry etching process, a wet etching process, a thermal etching process, or combinations thereof. In some embodiments, a source gas used in the dry etching process may include, for example, but not limited to, fluorine gas or a combination of fluorine gas and hydrogen fluoride gas. In some embodiments, when the dry etching process is a plasma etching process, a precursor for forming fluorine radicals may be used in the plasma etching process, and may include, for example, but not limited to, nitrogen trifluoride, fluoro-substituted hydrocarbon (e.g., fluoro-substituted methane, fluoro-substituted ethane, fluoro-substituted ethene, fluoro-substituted ethylene, or combinations thereof), sulfur hexafluoride, or combinations thereof. Other suitable source gases or precursors used in the dry etching process are within the contemplated scope of the present disclosure. In some embodiments, a digital oxidation technique combined with an etchant (e.g., hydrogen fluoride) may be used in the wet etching process. In some embodiments, a source gas used in the thermal etching process may include, for example, but not limited to, hydrogen chloride gas, chlorine gas, or a combination thereof. Other suitable source gases used in the thermal etching process are within the contemplated scope of the present disclosure. In some embodiments, the thermal etching process may be performed at a temperature ranging from about 300° C. to about 630° C.

When the sacrificial layer portions 17 are made of silicon oxide, the sacrificial layer portions 17 may be removed by a suitable etching process, for example, but not limited to, a dry etching process, a wet etching process, or a combination thereof. In some embodiments, a source gas used in the dry etching process may include, for example, but not limited to, hydrogen fluoride gas, ammonia gas, or a combination thereof. Other suitable source gases used in the dry etching process are within the contemplated scope of the present disclosure. In some embodiments, an etchant used in the wet etching process may include, for example, but not limited to, dilute hydrogen fluoride. Other suitable etchants used in the wet etching process are within the contemplated scope of the present disclosure.

When the sacrificial layer portions 17 are made of the polymeric material, the sacrificial layer portions 17 may be thermally decomposed (i.e., pyrolyzed) by a suitable thermal process, for example, but not limited to, an ashing process, a baking process, an annealing process, or combinations thereof. Other suitable thermal processes are within the contemplated scope of the present disclosure. In this case, the sacrificial layer portions 17 are thermally decomposed to form hydrocarbon gas, carbon oxide gas, hydrogen gas, or combinations thereof, and these gases may flow out through the semipermeable features 16. In some embodiments, the thermal process may be performed at a temperature ranging from about 200° C. to about 600° C. If the temperature is lower than 200° C., the sacrificial layer portions 17 may not be thermally decomposed.

In some embodiments, the sacrificial layer portions 17 has an etching selectivity greater than an etching selectivity of each of the semipermeable features 16 and the inner spacers 18, so that in this step, the sacrificial layer portions 17 can be efficiently removed to form the air inner spacers 23.

Referring to FIG. 1B and the example illustrated in FIG. 17, the method 100A then proceeds to step S16, where the gate dielectrics 24 and the gate electrodes 25 are formed in the cavities 21, 22. Step S16 may include sub-step (i) of sequentially forming layers of materials (not shown) for the gate dielectrics 24 and the gate electrodes 25 in the cavities 21, 22 by one or more suitable deposition processes (e.g., CVD, ALD, etc.), and sub-step (ii) of performing a planarization process (e.g., chemical mechanical polishing (CMP) or other suitable planarization processes) to remove an excess portion of each of the abovementioned layers of materials, thereby obtaining the gate dielectrics 24 and the gate electrodes 25. In some embodiments, the material for forming the gate dielectrics 24 may include, for example, but not limited to, silicon oxide, silicon nitride, silicon oxynitride, a suitable high-k material (e.g., hafnium oxide, zirconium oxide, zirconium aluminum oxide, hafnium aluminum oxide, hafnium silicon oxide, aluminum oxide, etc.), or combinations thereof. In some embodiments, each of the gate electrodes 25 may be configured as a multi-layered structure including at least one work function metal layer 251 which is provided for adjusting threshold voltage of an n-FET or a p-FET, and an electrically conductive layer 252 having a low resistance which is provided for reducing electrical resistance of the gate electrode 25. In some embodiments, the work function metal layer 251 of each of the gate electrodes 25 for forming an n-FET may be different from that for forming a p-FET so as to permit the n-FET and the p-FET to have different threshold voltages. In some embodiments, the work function metal layer 251 may have a p-type conductivity, and may include titanium nitride, tantalum nitride, ruthenium, molybdenum, tungsten, tungsten nitride, platinum, zirconium silicide, molybdenum silicide, tantalum silicide, nickel silicide, or combinations thereof. In some alternative embodiments, the work function metal layer 251 may have an n-type conductivity, and may include a metallic material (e.g., titanium, aluminum, silver, manganese, zirconium, or titanium aluminide), metal-containing nitrides (e.g., tantalum carbonitride, tantalum silicon nitride, or titanium silicon nitride), metal-containing carbides (e.g., tantalum carbide or titanium carbide), or combinations thereof. Other suitable materials for the work function metal layer 251 are within the contemplated scope of the present disclosure. In some embodiments, the electrically conductive layer 252 may include, for example, but not limited to, tungsten, aluminum, cobalt, or combinations thereof. Other suitable materials for the electrically conductive layer 252 are within the contemplated scope of the present disclosure. In some embodiments, each of the gate dielectrics 24 and a corresponding one of the gate electrodes 25 may be corporately referred to as a metal gate (i.e., a plurality of the metal gates are formed in this step), which is configured to surround corresponding ones of the channel features 122.

In some embodiments, a precursor may be used in formation of each of the gate dielectrics 24 and the gate electrodes 25, and may have a molecular size greater than about 5 Å. It is noted that, the precursor for forming each of the gate dielectrics 24 and the gate electrodes 25 is trapped by dangling bonds of the semipermeable features 16 (formed after step S14), and may not diffused into the air inner spacers 23.

After step S16, the semiconductor device 200A is obtained. In some embodiments, the semiconductor device 200A may be a nanosheet FET or a complementary FET (CFET). By forming the air inner spacers 23 (a k-value thereof is about 1.0), the semiconductor device 200A may have an improved device performance (e.g., alternating current (AC) performance gain and a reduced parasitic capacitance between the metal gates and the source/drain portions 19).

In some embodiments, after formation of the air inner spacers 23 (i.e., step S15) and before formation of the gate dielectrics 24 and the gate electrodes 25 (i.e., step S16), a plurality of interfacial features (not shown) are formed. Each of the interfacial features surrounds a corresponding one of the channel features 122 and is covered by a corresponding one of the gate dielectrics 24. In some embodiments, the interfacial features may include, for example, but not limited to, silicon oxide.

In some embodiments, the semiconductor device 200A includes a plurality of transistor structures, and each of the transistor structures includes two corresponding ones of the source/drain portions 19, corresponding ones of the channel features 122, a corresponding one of the metal gates, corresponding ones of the semipermeable features 16, corresponding ones of the inner spacers 18, and corresponding ones of the air inner spacers 23. In some embodiments, each of the semipermeable features 16 includes a main portion 16a (i.e., the semipermeable layer portion 162 with reference to FIG. 16) connected to the metal gate and two side portions 16b (i.e., remaining portions of the semipermeable layer portions 161 with reference to FIG. 16) extending from the main portion 16a to be respectively connected to two corresponding ones of the plurality of channel features 122.

FIG. 17B illustrates a semiconductor device 200B in accordance with some embodiments. The semiconductor device 200B is formed from the structure shown in FIG. 10A, and has a configuration similar to that of the semiconductor device 200A, except that, in the semiconductor device 200B, each of the two side portions 16b is disposed between a corresponding one of the channel features 122 and a corresponding one of the inner spacers 18.

In a semiconductor device of this disclosure, a plurality of air inner spacers are formed between a plurality of metal gates and a plurality of source/drain portions, which are conducive to reducing parasitic capacitance therebetween and improving device performance of the semiconductor device. In addition, processes for forming the air inner spacers may not adversely affect the source/drain portions or other components of the semiconductor device.

In accordance with some embodiments of the present disclosure, a method for manufacturing a semiconductor device includes: forming a stack portion on a substrate, the stack portion including a plurality of sacrificial features and a plurality of channel features which are alternately stacked on the substrate, so that a plurality of lateral recesses are formed beside the plurality of sacrificial features, each of the plurality of lateral recesses being formed between two corresponding ones of the plurality of the channel features; forming a plurality of semipermeable features in the plurality of lateral recesses, respectively, so that each of the plurality of semipermeable features laterally covers a corresponding one of the plurality of sacrificial features; forming a plurality of sacrificial layer portions on the plurality of semipermeable features, respectively, so that each of the plurality of sacrificial layer portions is disposed on a corresponding one of the plurality of semipermeable features opposite to a corresponding one of the plurality of sacrificial features; forming a plurality of inner spacers on the plurality of sacrificial layer portions, respectively, so that each of the plurality of inner spacers laterally covers a corresponding one of the plurality of sacrificial layer portions; removing the plurality of sacrificial features so as to form a plurality of cavities; treating the plurality of semipermeable features with an etching process; and removing the plurality of sacrificial layer portions through the plurality of semipermeable features treated with the etching process, so as to form a plurality of air inner spacers, each of which is defined by a corresponding one of the plurality of semipermeable features and a corresponding one of the plurality of inner spacers.

In accordance with some embodiments of the present disclosure, the plurality of semipermeable features, the plurality of sacrificial layer portions, and the plurality of inner spacers are formed by conformally depositing a semipermeable layer made of a low dielectric-constant dielectric material to cover the stack portion; forming a sacrificial layer on the semipermeable layer; removing a portion of the sacrificial layer to form the plurality of sacrificial layer portions on the semipermeable layer; forming a spacer material layer on the semipermeable layer to cover the plurality of sacrificial layer portions; and removing portions of the semipermeable layer and a portion of the spacer material layer to form the plurality of semipermeable features and the plurality of inner spacers.

In accordance with some embodiments of the present disclosure, the low dielectric-constant dielectric material includes silicon carbonitride, silicon oxycarbonitride, or a combination thereof.

In accordance with some embodiments of the present disclosure, the semipermeable layer is formed by an atomic layer deposition process.

In accordance with some embodiments of the present disclosure, the plurality of semipermeable features, the plurality of sacrificial layer portions, and the plurality of inner spacers are formed by subjecting the stack portion to a self-aligned oxidation process to form a semipermeable layer on the stack portion, the semipermeable layer being made of a self-aligned oxidation material; forming a sacrificial layer on the semipermeable layer; removing a portion of the sacrificial layer and portions of the semipermeable layer to form the plurality of sacrificial layer portions and the plurality of semipermeable features; forming a spacer material layer on the stack portion to cover the plurality of sacrificial layer portions and the plurality of semipermeable features; and removing a portion of the spacer material layer to form the plurality of inner spacers.

In accordance with some embodiments of the present disclosure, the plurality of channel features include silicon, the plurality of sacrificial features include silicon germanium, and the self-aligned oxidation material includes silicon oxide, silicon germanium oxide, or a combination thereof.

In accordance with some embodiments of the present disclosure, the etching process is a dry etching process performed using a source gas which includes a hydrogen chloride gas, a chlorine gas, a hydrogen fluoride gas, an ammonia gas, a fluorine gas, or combinations thereof.

In accordance with some embodiments of the present disclosure, the etching process is a wet etching process performed using an etchant which includes hydrofluoric acid.

In accordance with some embodiments of the present disclosure, a method for manufacturing a semiconductor device includes: forming a first stack portion and a second stack portion on a substrate, the first stack portion and the second stack portion being spaced apart from each other by a trench, each of the first stack portion and the second stack portion including a plurality of sacrificial features and a plurality of channel features which are alternately stacked on the substrate, so that a plurality of lateral recesses are formed beside the plurality of sacrificial features, each of the plurality of lateral recesses being formed between two corresponding ones of the plurality of channel features; forming a plurality of semipermeable features in the plurality of lateral recesses, respectively, so that each of the plurality of semipermeable features laterally covers a corresponding one of the plurality of sacrificial features; forming a plurality of sacrificial layer portions on the plurality of semipermeable features, respectively, so that each of the plurality of sacrificial layer portions is disposed on a corresponding one of the plurality of semipermeable features opposite to a corresponding one of the plurality of sacrificial features; forming a plurality of inner spacers on the plurality of sacrificial layer portions, respectively, so that each of the plurality of inner spacers laterally covers a corresponding one of the plurality of sacrificial layer portions and is exposed to the trench; removing the plurality of sacrificial features so as to form a plurality of cavities; treating the plurality of semipermeable features with an etching process; and removing the plurality of sacrificial layer portions through the plurality of semipermeable features treated with the etching process, so as to form a plurality of air inner spacers, each of which is defined by a corresponding one of the plurality of semipermeable features and a corresponding one of the plurality of inner spacers.

In accordance with some embodiments of the present disclosure, the plurality of sacrificial layer portions include silicon germanium, silicon oxide, a polymeric material, or combinations thereof.

In accordance with some embodiments of the present disclosure, the plurality of sacrificial layer portions include silicon germanium, and are removed by a dry etching process performed using a source gas which includes fluorine gas, hydrogen fluoride gas, or a combination thereof.

In accordance with some embodiments of the present disclosure, the plurality of sacrificial layer portions include silicon germanium, and are removed by a plasma etching process performed using a precursor for forming fluorine radicals. The precursor includes nitrogen trifluoride, fluoro-substituted methane, fluoro-substituted ethane, fluoro-substituted ethene, fluoro-substituted ethylene, sulfur hexafluoride, or combinations thereof.

In accordance with some embodiments of the present disclosure, the plurality of sacrificial layer portions include silicon germanium, and are removed by a wet etching process performed using an etchant which includes hydrogen fluoride.

In accordance with some embodiments of the present disclosure, the plurality of sacrificial layer portions include silicon germanium, and are removed by a thermal etching process performed using a source gas which includes hydrogen chloride gas, chlorine gas, or a combination thereof.

In accordance with some embodiments of the present disclosure, the plurality of sacrificial layer portions include silicon oxide, and are removed by a dry etching process performed using a source gas which includes hydrogen fluoride gas, ammonia gas, or a combination thereof.

In accordance with some embodiments of the present disclosure, the plurality of sacrificial layer portions include silicon oxide, and are removed by a wet etching process performed using an etchant which includes hydrogen fluoride.

In accordance with some embodiments of the present disclosure, the plurality of sacrificial layer portions include the polymeric material including carbon, hydrogen, oxygen, silicon, nitrogen, or combinations thereof, and are removed by an ashing process, a baking process, an annealing process, or combinations thereof.

In accordance with some embodiments of the present disclosure, a semiconductor device includes a substrate, a first source/drain portion, a second source/drain portion, a plurality of channel features, a metal gate, a plurality of semipermeable features, and a plurality of inner spacers. The first source/drain portion and the second source/drain portion are disposed on the substrate and are spaced apart from each other in a first direction parallel to a lower surface of the substrate. The plurality of channel features are disposed between and connected to the first source/drain portion and the second source/drain portion. The plurality of channel features are spaced apart from one another in a second direction transverse to the first direction and normal to the lower surface of the substrate. The metal gate is disposed to surround the plurality of channel features. Each pair of the plurality of semipermeable features is disposed at two opposite sides of the metal gate. Each of the plurality of inner spacers is disposed to cooperate with a corresponding one of the plurality of semipermeable features to define an air inner spacer.

In accordance with some embodiments of the present disclosure, each of the plurality of semipermeable features includes a main portion connected to the metal gate and two side portions extending from the main portion to be respectively connected to two corresponding ones of the plurality of channel features.

In accordance with some embodiments of the present disclosure, each of the plurality of semipermeable features includes a main portion connected to the metal gate and two side portions extending from the main portion so that each of the two side portions is disposed between a corresponding one of the plurality of channel features and a corresponding one of the plurality of inner spacers.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a stack portion on a substrate, the stack portion including a plurality of sacrificial features and a plurality of channel features which are alternately stacked on the substrate, so that a plurality of lateral recesses are formed beside the plurality of sacrificial features, each of the plurality of lateral recesses being formed between two corresponding ones of the plurality of the channel features;
forming a plurality of semipermeable features in the plurality of lateral recesses, respectively, so that each of the plurality of semipermeable features laterally covers a corresponding one of the plurality of sacrificial features;
forming a plurality of sacrificial layer portions on the plurality of semipermeable features, respectively, so that each of the plurality of sacrificial layer portions is disposed on a corresponding one of the plurality of semipermeable features opposite to a corresponding one of the plurality of sacrificial features;
forming a plurality of inner spacers on the plurality of sacrificial layer portions, respectively, so that each of the plurality of inner spacers laterally covers a corresponding one of the plurality of sacrificial layer portions;
removing the plurality of sacrificial features so as to form a plurality of cavities;
treating the plurality of semipermeable features with an etching process; and
removing the plurality of sacrificial layer portions through the plurality of semipermeable features treated with the etching process, so as to form a plurality of air inner spacers, each of which is defined by a corresponding one of the plurality of semipermeable features and a corresponding one of the plurality of inner spacers.

2. The method as claimed in claim 1, wherein the plurality of semipermeable features, the plurality of sacrificial layer portions, and the plurality of inner spacers are formed by
conformally depositing a semipermeable layer made of a low dielectric-constant dielectric material to cover the stack portion;
forming a sacrificial layer on the semipermeable layer;
removing a portion of the sacrificial layer to form the plurality of sacrificial layer portions on the semipermeable layer;
forming a spacer material layer on the semipermeable layer to cover the plurality of sacrificial layer portions; and
removing portions of the semipermeable layer and a portion of the spacer material layer to form the plurality of semipermeable features and the plurality of inner spacers.

3. The method as claimed in claim 2, wherein the low dielectric-constant dielectric material includes silicon carbonitride, silicon oxycarbonitride, or a combination thereof.

4. The method as claimed in claim 2, wherein the semipermeable layer is formed by an atomic layer deposition process.

5. The method as claimed in claim 1, wherein the plurality of semipermeable features, the plurality of sacrificial layer portions, and the plurality of inner spacers are formed by
subjecting the stack portion to a self-aligned oxidation process to form a semipermeable layer on the stack portion, the semipermeable layer being made of a self-aligned oxidation material;
forming a sacrificial layer on the semipermeable layer;
removing a portion of the sacrificial layer and portions of the semipermeable layer to form the plurality of sacrificial layer portions and the plurality of semipermeable features;
forming a spacer material layer on the stack portion to cover the plurality of sacrificial layer portions and the plurality of semipermeable features; and
removing a portion of the spacer material layer to form the plurality of inner spacers.

6. The method as claimed in claim 5, wherein the plurality of channel features include silicon, the plurality of sacrificial features include silicon germanium, and the self-aligned oxidation material includes silicon oxide, silicon germanium oxide, or a combination thereof.

7. The method as claimed in claim 1, wherein the etching process is a dry etching process performed using a source gas which includes a hydrogen chloride gas, a chlorine gas, a hydrogen fluoride gas, an ammonia gas, a fluorine gas, or combinations thereof.

8. The method as claimed in claim 1, wherein the etching process is a wet etching process performed using an etchant which includes hydrofluoric acid.

9. A method for manufacturing a semiconductor device, comprising:
forming a first stack portion and a second stack portion on a substrate, the first stack portion and the second stack portion being spaced apart from each other by a trench, each of the first stack portion and the second stack portion including a plurality of sacrificial features and a plurality of channel features which are alternately stacked on the substrate, so that a plurality of lateral recesses are formed beside the plurality of sacrificial features, each of the plurality of lateral recesses being formed between two corresponding ones of the plurality of channel features;
forming a plurality of semipermeable features in the plurality of lateral recesses, respectively, so that each of the plurality of semipermeable features laterally covers a corresponding one of the plurality of sacrificial features;
forming a plurality of sacrificial layer portions on the plurality of semipermeable features, respectively, so that each of the plurality of sacrificial layer portions is disposed on a corresponding one of the plurality of semipermeable features opposite to a corresponding one of the plurality of sacrificial features;
forming a plurality of inner spacers on the plurality of sacrificial layer portions, respectively, so that each of the plurality of inner spacers laterally covers a corresponding one of the plurality of sacrificial layer portions and is exposed to the trench;
removing the plurality of sacrificial features so as to form a plurality of cavities;
treating the plurality of semipermeable features with an etching process; and
removing the plurality of sacrificial layer portions through the plurality of semipermeable features treated with the etching process, so as to form a plurality of air inner spacers, each of which is defined by a corresponding one of the plurality of semipermeable features and a corresponding one of the plurality of inner spacers.

10. The method as claimed in claim 9, wherein the plurality of sacrificial layer portions include silicon germanium, silicon oxide, a polymeric material, or combinations thereof.

11. The method as claimed in claim 10, wherein the plurality of sacrificial layer portions include silicon germanium, and are removed by a dry etching process performed using a source gas which includes fluorine gas, hydrogen fluoride gas, or a combination thereof.

12. The method as claimed in claim 10, wherein the plurality of sacrificial layer portions include silicon germanium, and are removed by a plasma etching process performed using a precursor for forming fluorine radicals, the precursor including nitrogen trifluoride, fluoro-substituted methane, fluoro-substituted ethane, fluoro-substituted ethene, fluoro-substituted ethylene, sulfur hexafluoride, or combinations thereof.

13. The method as claimed in claim 10, wherein the plurality of sacrificial layer portions include silicon germanium, and are removed by a wet etching process performed using an etchant which includes hydrogen fluoride.

14. The method as claimed in claim 10, wherein the plurality of sacrificial layer portions include silicon germanium, and are removed by a thermal etching process performed using a source gas which includes hydrogen chloride gas, chlorine gas, or a combination thereof.

15. The method as claimed in claim 10, wherein the plurality of sacrificial layer portions include silicon oxide, and are removed by a dry etching process performed using a source gas which includes hydrogen fluoride gas, ammonia gas, or a combination thereof.

16. The method as claimed in claim 10, wherein the plurality of sacrificial layer portions include silicon oxide, and are removed by a wet etching process performed using an etchant which includes hydrogen fluoride.

17. The method as claimed in claim 10, wherein the plurality of sacrificial layer portions include the polymeric material including carbon, hydrogen, oxygen, silicon, nitrogen, or combinations thereof, and are removed by an ashing process, a baking process, an annealing process, or combinations thereof.

18. A semiconductor device, comprising:
a substrate;
a first source/drain portion and a second source/drain portion disposed on the substrate and spaced apart from each other in a first direction parallel to a lower surface of the substrate;
a plurality of channel features disposed between and connected to the first source/drain portion and the second source/drain portion, the plurality of channel features being spaced apart from one another in a second direction transverse to the first direction and normal to the lower surface of the substrate;
a metal gate disposed to surround the plurality of channel features;
a plurality of semipermeable features, each pair of the plurality of semipermeable features being disposed at two opposite sides of the metal gate; and
a plurality of inner spacers, each of which is disposed to cooperate with a corresponding one of the plurality of semipermeable features to define an air inner spacer.

19. The semiconductor device as claimed in claim 18, wherein each of the plurality of semipermeable features includes a main portion connected to the metal gate and two side portions extending from the main portion to be respectively connected to two corresponding ones of the plurality of channel features.

20. The semiconductor device as claimed in claim 18, wherein each of the plurality of semipermeable features includes a main portion connected to the metal gate and two side portions extending from the main portion so that each of the two side portions is disposed between a corresponding one of the plurality of channel features and a corresponding one of the plurality of inner spacers.
